(19) United States
(12) Patent Application Publication
(10) Pub. No.: US 2006/0266403 A1
(43) Pub. Date: Nov. 30, 2006

(54) Quick attaching thermoelectric device

(76) Inventor: Nathan Hiller, Fallbrook, CA (US)

Correspondence Address: John R. Ross, PO Box 2138, Del Mar, CA, 92014, US

(21) Appl. No.: 11/138,741

(22) Filed: May 25, 2005

(51) Int. Cl. H01L 35/30

(52) U.S. Cl. 136/205

(57) ABSTRACT

A quickly attachable electric generator system for producing electric power from hot or cold surfaces of magnetic materials. The system includes at least one permanent magnet for providing a magnetic attractive force to hold a surface of a thermoelectric module against the hot or cold surfaces. In a preferred embodiment, useful for attaching to the tail pipe or muffler of a motor vehicle, a thin flexible high heat conducting copper disk is braised to a thin bottom portion of a copper pedestal that has a wider flat upper portion. The wider flat upper portion is the heat source of a thermoelectric module that is compressed between it and an aluminum fin unit functioning as a heat sink. Insulating wafers on both the hot and cold sides to the thermoelectric module provide electrical insulation of the module from the copper pedestal and the finned heat sink. Heat conducting grease is used to improve thermal conductivity. In this preferred embodiment 24 small cylindrical magnets are positioned around a mid section of the pedestal in 12 aluminum bottomless cups positioned between the thin copper disk and the wide flat portion of the pedestal. When in use the thin flexible disk conforms to the surface shape of the steel (or other iron containing material) to which it is attached, and the disk along with the rest of the thermoelectric generator is held in place by the magnetic force of the 24 magnets. When attached to a tail pipe heat flows from the hot surface of the tail pipe through the thin flexible copper disk, through the pedestal to provide a heat source at a temperature in the range of about 450 degrees F. for the thermoelectric module. The fin unit provides the heat sink transferring heat to the atmosphere to provide a cold surface at about 85 degrees for a temperature difference of about 365 degrees F. In this preferred embodiment the module is utilized to provide electric power to power a transmitter to transmit information regarding the location of the motor vehicle to which it is attached. Standard thermoelectric modules available on the market can be utilized.

The present invention relates to thermoelectric devices and in particular techniques for producing electric power from existing heat sources.

### BACKGROUND OF THE INVENTION

A well-known use for thermoelectric devices is for the extraction of electric power from waste heat. For example, U.S. Pat. No. 6,527,548 discloses a self powered space heater for a truck in which heat energy for the heater is used to power electric components of the heater plus charge a battery. In U.S. Pat. No. 6,053,163 heat from a stovepipe is used to generate electricity. U.S. Pat. No. 6,019,098 discloses a self-powered furnace. Various types of thermoelectric modules are available. A very reliable thermoelectric module with a gap-less egg-crate design is described in U.S. Pat. Nos. 5,875,098 and 5,856,210. U.S. Pat. No. 6,207,887 discloses a miniature milli-watt thermoelectric module useful in space applications (and special applications on earth) in combination with radioactive heat source.

A typical thermoelectric module is Hi-Z Model HZ-2, commercially available from Hi-Z Corporation with offices in San Diego, Calif. It is a square module with 2.9 cm sides and is 0.5 cm thick. It produces about 2 watts at 4 volts when sandwiched between hot and cold surfaces with a temperature difference of about 200 degrees centigrade. This unit sells for less than $50.

Quantum well very thin layer thermoelectric modules are known. Some are described in U.S. Pat. Nos. 6,096,965, 6,096,964, 5,436,467 and 5,550,387. U.S. Pat. No. 6,624,349 describes an electric generator using a thermoelectric module to generate electric power from the heat of fusion produced by the freezing of a phase change material. All of these patents are assigned to Applicant's employer and they are all incorporated herein by reference.

Workers in the thermoelectric industry have been attempting too improve performance of thermoelectric devices for the past 20-30 years with not much success. Most of the effort has been directed to reducing the lattice thermal conductivity (K) without adversely affecting the electrical conductivity. Experiments with superlattice quantum well materials have been underway for several years. These materials were discussed in an paper by Gottfried H. Dohler which was published in the November 1983 issue of Scientific American. This article presents an excellent discussion of the theory of enhanced electric conduction in superlattices. These superlattices contain alternating conducting and barrier layers and create quantum wells that improve electrical conductivity. These superlattice quantum well materials are crystals grown by depositing semiconductors in layers each layer with a thickness in the range of a few to up to about 100 angstroms. Thus, each layer is only a few atoms thick. (These quantum well materials are also discussed in articles by Hicks, et al and Harman published in Proceedings of 1992 1st National Thermoelectric Cooler Conference Center for Night Vision & Electro Optics, U.S.Army, Fort Belvoir, Va. The articles project theoretically very high ZT values as the layers are made progressively thinner.) The idea being that these materials might provide very great increases in electric conductivity without adversely affecting Seebeck coefficient or the thermal conductivity. Harmon of Lincoln Labs, operated by MIT has claimed to have produced a superlattice of layers of (Bi,Sb) and Pb(Te,Se). He claims that his preliminary measurements suggest ZTs of 3 to 4. FIG. 1 shows theoretical calculated values (Sun et al—1998) of ZT plotted as a function of quantum well width.

Tracking and surveillance devices are available for tracking vehicles. Devices are available that can be attached to an motor vehicle that will transmit radio signals indicating the latitude and longitude of the motor vehicle to a monitoring stations. Trucking systems can use these systems to keep track of its vehicles as they traverse the United States. Police can attach these devices to motor vehicles of evil people to keep track of them. These devices are typically powered by batteries so that their useful life is limited. A typical tracking device is a Model ST-18 PTT available from Telonics, Inc with offices in Mesa Ariz. The unit operates at 4 volts and requires about ½ watt to transmit via the Argos tracking system. Argos is a satellite-based system in operation since the late 1970's and is utilized world wide to track just about anything from ships, to trucks to birds.

The phrase “magnetic materials” is a phrase generally applied to materials exhibiting ferromagnetism. In this patent application the phrase will be used to describe materials such as iron, nickel or cobalt and alloys of these material and products made from these materials and their alloys (such as tail pipes and mufflers) to which magnets are strongly attracted.

What is needed is a product that can produce small amounts of electric power from a hot or cold surface and can be attached to the surface quickly and easily.

### SUMMARY OF THE INVENTION

The present invention provides a quickly attachable electric generator system for producing electric power from hot or cold surfaces of magnetic materials. The system includes at least one permanent magnet for providing a magnetic attractive force to hold a surface of a thermoelectric module against the hot or cold surfaces. In a preferred embodiment, useful for attaching to the tail pipe or muffler of a motor vehicle, a thin flexible high heat conducting copper disk is braised to a thin bottom portion of a copper pedestal that has a wider flat upper portion. The wider flat upper portion is the heat source collector of a thermoelectric module that is compressed between it and an aluminum fin unit functioning as a heat sink. Insulating wafers on both the hot and cold sides to the thermoelectric module provide electrical insulation of the module from the copper pedestal and the finned heat sink. Heat conducting grease is used to improve thermal conductivity. In this preferred embodiment 24 small cylindrical magnets are positioned around a mid section of the pedestal in 12 aluminum bottomless cups positioned between the thin copper disk and the wide flat portion of the pedestal. When in use the thin flexible disk conforms to the surface shape of a steel (or other iron containing material) surface to which it is attached, and the disk along with the rest of the thermoelectric generator is held in place by the magnetic force of the 24 magnets. When attached to a tail pipe of a motor vehicle, heat flows from the hot surface of the tail pipe through the thin flexible copper disk, through the pedestal to provide a heat source at a temperature in the range of about 450 degrees F. for the thermoelectric module. The fin unit provides the heat sink transferring heat to the atmosphere to provide a “cold” surface at about 85 degrees for a temperature difference of about 365 degrees F. In this preferred embodiment the module is utilized to provide electric power to power a transmitter to transmit information regarding the location of the motor vehicle to which it is attached. Standard thermoelectric modules available on the market can be utilized.

For highest module efficiencies quantum well modules are preferred with p-legs and n-legs, each leg being comprised of a large number of at least two different very thin alternating layers of elements. For applications where the temperature range is relatively low, a preferred quantum well choice is n-doped Si/SiGe for the n-legs and p-doped Si/SiGe for the p-legs. At higher temperatures the preferred quantum well legs are alternating layers of silicon and silicon carbide for the n-legs and for the p-legs alternating layers of different stoichiometric forms of B-C.

### BRIEF DESCRIPTION OF THE DRAWINGS

FIGS. 1A through 6 show the steps of assembling a preferred embodiment of the present invention.

FIG. 7 show the preferred embodiment in use for tracking a motor vehicle.

FIG. 8A and 8B show how to assemble a second preferred embodiment.

### DETAILED DESCRIPTION OF PREFERRED EMBODIMENT

### First Preferred Embodiment

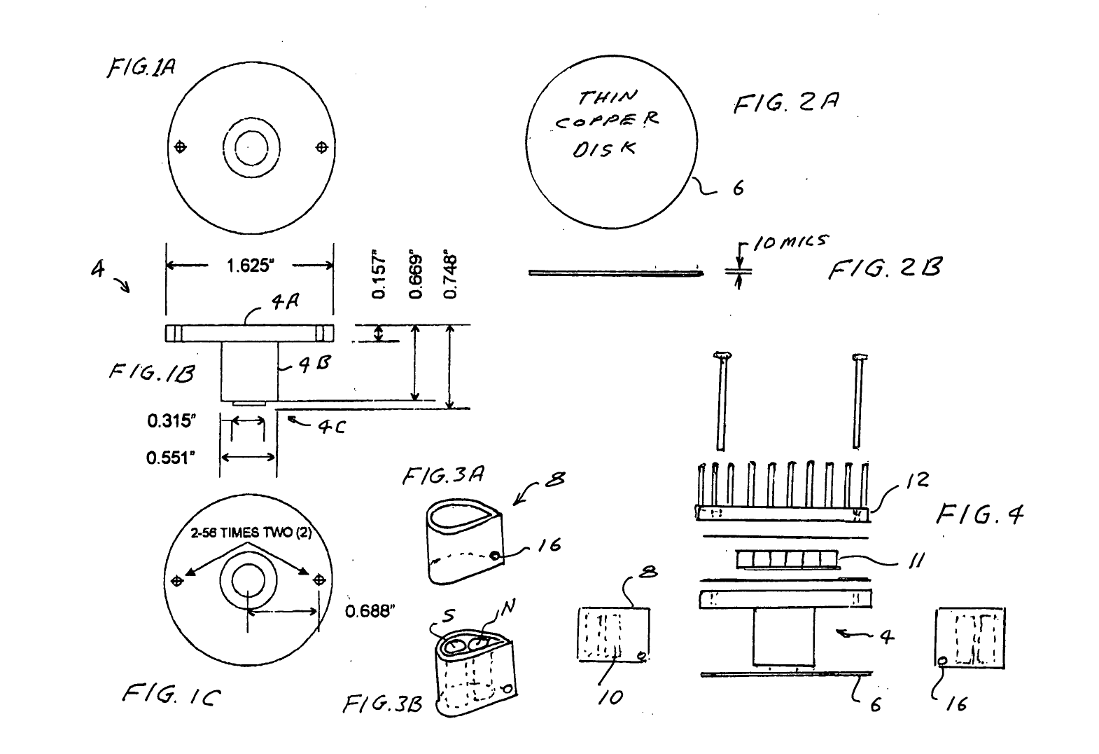

FIGS. 1A through 7 show the basic features of a first preferred embodiments of the present invention. In this embodiment a thermoelectric generator is attached to a cylindrical steel tail pipe of a motor vehicle with the magnetic force of a plurality of magnets that compresses a thin flexible high heat conducting element against the tail pipe. Preferably, the thin flexible high heat conducting element is a thin copper disk and it is braised to a thin bottom portion of a copper pedestal that has a wider flat upper portion. The wider flat upper portion is the heat source of a thermoelectric module that is compressed between an aluminum fin unit functioning as a heat sink and the flat upper portion of the pedestal. Insulating wafers on both the hot and cold sides to the thermoelectric module provide electrical insulation of the module from the copper pedestal and the finned heat sink. Heat conducting grease is used to improve thermal conductivity. In this preferred embodiment 24 small cylindrical magnets are positioned around a mid section of the pedestal in 12 aluminum bottomless cups between the thin copper disk and the wide flat portion of the pedestal. When in use the thin flexible disk conforms to the shape of the steel (or other iron containing material) surface to which it is attached, and the disk along with the rest of the thermoelectric generator is held in place by the magnetic force of the 24 magnets.

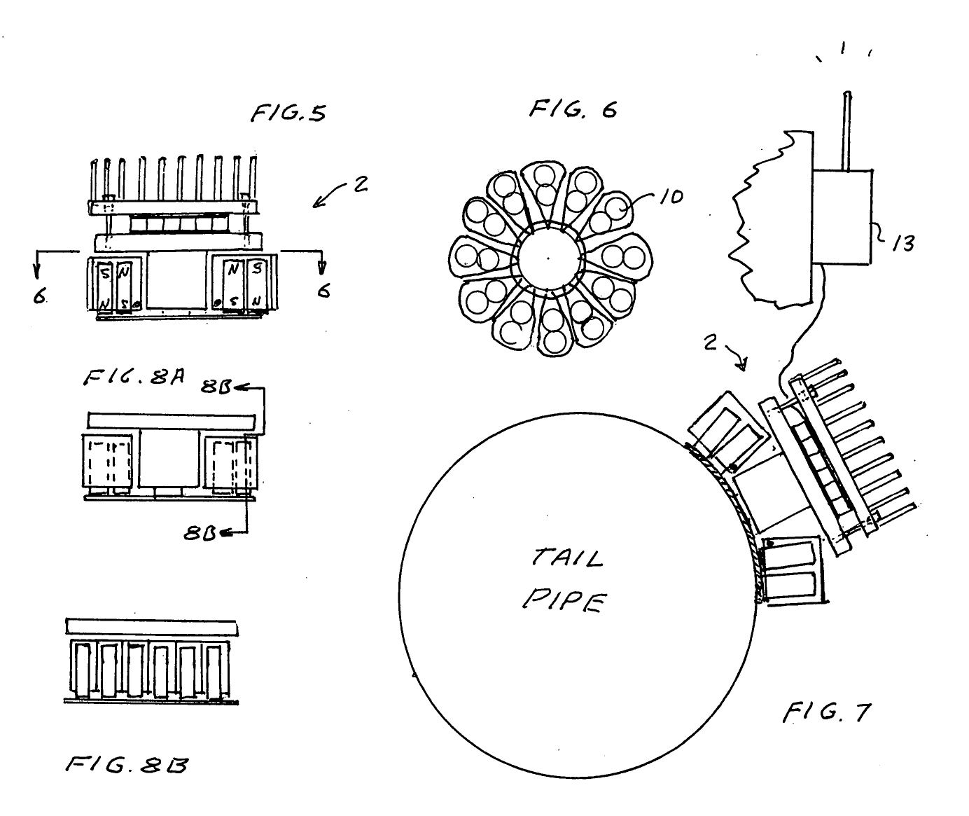

FIGS. 1A, 1B and 1C show a preferred pedestal 4 for the first preferred embodiment. It is machined from copper. The wider flat upper portion 4A has a top surface with a diameter of 1.625 inches, a 0.551 inch diameter middle section 4B and the thin bottom portion 4C has a diameter of 0.315 inch. The thin flexible copper disk 6 is 10 mils thick and has a diameter of 1.625 inches. It is braised to the bottom surface of the pedestal as shown in FIG. 4. Twelve bottomless cups 8 for holding the magnets 10 are made from ⅝ inch aluminum streamline tubing by cutting the tubing into 0.47 inch lengths. One of those cups is shown in FIG. 3A. FIG. 3B shows two magnets 10 positioned in the cup. The magnets are samarium cobalt magnets, 0.47 inch in length. The diameter of the inside magnet is 0.203 inch and the diameter of the outside magnet is 0.234 inch. The magnets are available from Chen Yang Engineering located at Franz-Brombach-STR 11-13, D-85435 Erding, Germany. The parts of the thermoelectric generator are shown blown up in FIG. 4. These parts include pedestal 4, cups 8 and magnets 10. The thermoelectric module used in this preferred embodiment is a 2 ½ watt thermoelectric module, Model HZ—2 available from Hi-Z corporation with offices in San Diego, Calif. It is 1.15 inch square and 0.2 inch thick. It produces more than 2 watts at 4 volts with a 365 degree F. (300 degree C.) hot to cold temperature difference. The finned heat sink 12 is a molded aluminum fin unit that is available commercially from Alpha NovaTec located at 4733 Sapena Ct. #15, Santa Clara, Calif. 95054. The preferred unit has a square flat surface with sides 1.8 inches long. Its thickness to the tips of its thin cylindrical fins is about ½ inch. The thermoelectric module is electrically insulated from heat sink 12 and pedestal 4 by 10-mil thick alumina wafers 14. Heat conducting grease such as a mixture of 30% diffusion pump oil and 70% boron nitride is applied at each heat transfer intersection to improve heat conductivity. The bottomless cups are held in place by a thin wire that is run through holes 16 located at the bottom of the cups 8. The cups can be installed around the pedestal as follows: Drill a small hole in the outside surface of one of the cups, the “first cup”. Cut a 6 inch length of thin flexible wire and form a 0.1 inch loop in one end of the wire. String the other end through hole 16 of the first cup then through hole 16 of the other eleven cups. Then run the end of the wire through the 0.1 inch loop. Place the cups around pedestal 4 and tighten the wire so that the twelve cups encircle pedestal 4 closely, but with some room to allow the cups to move radially with respect to the wire. Wrap a portion of the loose section of the wire around the screw and cut off the excess portion of the wire. FIG. 5 shows the thermoelectric generator 2 fully assembled. FIG. 6 shows the location of magnets 10. FIG. 7 shows generator 2 attached to the surface of a cylindrical tail pipe. This unit attaches equally well to any cylindrical, spherical or flat surface and other surface shapes as long with radii of curvature of more than about 1 ½ inch. The surface should be relatively clean. A little heat conducting grease will usually improve performance. The FIG. 7 drawing shows generator 2 providing power to a transmitter such as Model ST-18 PTT available form Telonics, Inc with offices in Mesa, Ariz.

### Second Preferred Embodiment

A second preferred embodiment of the present invention is shown in FIGS. 8A and 8B. This unit is exactly the same as the generator of the first preferred embodiment except the thin bottom part of pedestal 4 is rectangular rather than circular. This second preferred embodiment is useful for attachment to flat and cylindrical surfaces but would not attach very well to spherical surfaces. Also, when attaching it to cylindrical surfaces care must be taken to line it up with the axis of the cylindrical surface. It should attach very well however to tail pipes and mufflers of motor vehicles.

While the above description contains many specificities, the reader should not construe these as limitations on the scope of the invention, but merely as exemplifications of preferred embodiments thereof. Those skilled in the art will envision many other possible variations within its scope. For example:
The bismuth telluride N and P legs used in the thermoelectric module can be replaced by other types of thermoelectric materials including nanostructures such as quantum wells, quantum wires, and quantum dots.
The samarium cobalt magnets can be replaced by other high temperature magnets.
The electrical insulators can be replaced with heat transfer grease that is electrical insulating such as a mixture of diffusion oil, boron nitride, and diamond dust.
The aluminum heat sink can be made from more thermally conductive materials such as copper or aluminum copper combinations.
The pedestal can be made of aluminum to reduce the mass of the device.
If the heat source or heat sink is flat, a thicker copper plate may be used because flexibility is not needed.
Multiple devices can be attached together using flexible attachments so that higher voltages and power can be obtained.
More than one module can be sandwiched between the pedestal and the heat sink fins. These modules may be electrical connected in series or parallel.
The heat sink may extend beyond and below the pedestal for maximum heat transfer.
Instead of brazing the copper plate to the pedestal, a screw, clamp, rivet, or other mechanical fastening mechanism may be employed.
High-temperature thermal insulators, such as Teflon PFA, may be used as washers to thermally isolate the compression bolts that hold the module in place. These washers will increase the device power and voltage because less heat will leak through the compression bolts.
The heat sink may be painted such that the device is camouflaged against the muffler backdrop.
The tracking unit can be attached to the top of the heat sink and separated using thermal isolating washers such as Teflon PFA.
Wires may be used to compress the module instead of bolts.
The heat sink and pedestal can be made as one piece with the slot for the module to slip in to along with a highly thermal expansion material so that upon heating the module will experience a compressive force.
Belleville washers can be used on each bolt to increase uniform loading on the module.
The copper plate can be sliced into multiple sheets, like ma pie, to increase the plate flexibility.
A single bolt can be used to compress the module, instead of two bolts, if one side of the fined heat sink is fixed to the pedestal at the module height.

Accordingly, the reader is requested to determine the scope of the invention by the appended claims and their legal equivalents, and not by the examples which have been given.

We claim:

1. A quick attachable electric generator system for producing electric power from a hot or cold surface of a magnetic material, said system comprising:
A) a heat conducting pedestal having a flat top surface and a bottom surface with at least one thin dimension,
B) a thin flexible high heat conducting element attached to and in thermal communication with said bottom surface of said pedestal,
C) at least one permanent magnet for providing a magnetic attractive force to hold a surface of said thin flexible high heat conducting element against the hot or cold surface of the magnetic material,
D) a heat sink element, and
E) a thermoelectric module held in compression between said flat top surface of said pedestal and said heat sink element.

2. The system as in claim 1 and further comprising insulating wafers positioned on two sides of said module and providing electrical insulation of said module from said pedestal and said heat sink.

3. The system as in claim 1 wherein said pedestal is generally cylindrical with circular cross sections and said bottom surface is circular and said at least one permanent magnet is a plurality of magnets positioned around said pedestal in bottomless cups.

4. The system as in claim 1 wherein said pedestal is generally prismatic with rectangular cross sections and said bottom surface is rectangular with a thin dimension and a long dimension and said at least one permanent magnet is a plurality of magnets positioned on opposite sides of said pedestal in bottomless cups.

5. The system as in claim 1 wherein said heat sink is a finned aluminum element with thin cylindrical fins.

6. The system as in claim 1 wherein said system is attached to a tail pipe or muffler of a motor vehicle.

7. The system as in claim 6 wherein said system in electrical communication with and is providing electrical power to a radio frequency transmitter.

8. The generator as in claim 1 wherein said generator comprises at least one thermoelectric module comprised of thin film thermoelectric n-legs and p-legs.

9. The generator as in claim 1 wherein said generator comprises:
A) a plurality of n-legs comprised of very thin alternating layers of silicon and silicon carbide; and
B) a plurality of p-legs,;
said p-legs and said n-legs being electrically connected to produce said thermoelectric module.

10. A thermoelectric module as in claim 8 wherein said p-legs comprise very thin alternating layers of boron carbide.

11. A thermoelectric module as in claim 9 wherein said very thin alternating layers of boron carbide comprise two different stoichiometric forms of boron carbide.

12. A thermoelectric module as in claim 8 wherein said alternating layers are deposited on a substrate.

13. A thermoelectric module as in claim 15 wherein said substrate is a polyimide substrate.

14. A thermoelectric module as in claim 13 wherein said substrate is silicon
